(19) United States
(12) Patent Application Publication
(10) Pub. No.: US 2005/0231211 A1
(43) Pub. Date: Oct. 20, 2005

(54) Continuity tester with magnetic ground and method therefor

(76) Inventor: David R. Fleming, Cottonwood, AZ (US)

Correspondence Address: WEISS & MOY PC, 4204 NORTH BROWN AVENUE, SCOTTSDALE, AZ, 85251, US

(21) Appl. No.: 11/102,960

(22) Filed: Apr. 11, 2005

Related U.S. Application Data
(60) Provisional application No. 60/562,951, filed on Apr. 16, 2004.

(51) Int. Cl. G01R 31/02

(52) U.S. Cl. 324/555

(57) ABSTRACT

A continuity testing device has a probe element for contacting a conductor. A continuity testing circuit is coupled to the probe element. The continuity testing circuit has at least one of a vibrating or audible sensor to indicate electrical continuity of the conductor. A grounding wire is coupled to the continuity testing circuit. The grounding wire has a magnetic contact coupled thereto to ground the continuity testing device to any ferrous metallic grounded element. A housing is provided for holding and storing the probe element and the continuity testing circuit.

### RELATED APPLICATIONS

This patent application is claiming the benefit of U.S. Provisional Application entitled “CONTINUITY TESTER WITH MAGNETIC GROUND”, filed on Apr. 16, 2004, having a Ser. No. 60/562,951, and in the name of Fleming et al.

### BACKGROUND OF THE INVENTION

1. Field of the Invention

This invention relates to testing equipment and, more specifically, to a continuity tester which uses a magnet for grounding the continuity tester and which further has two separate signaling devices for indicating electrical continuity of an electrical conductor.

2. Description of the Prior Art

In general, a continuity tester is used to determine whether or not circuit continuity exists between probe points, an electrical conductor, etc. Most continuity testers have one or more probes. The probe is coupled in series with a source of potential. If continuity exists, a lamp unit in the continuity tester will illuminate indicating continuity is established. If no continuity exists, the light will fail to illuminate.

While current continuity testers do work, they have several drawbacks. First, when using the continuity tester outdoors, it is difficult to tell if the lamp unit is illuminated. This is due to the fact that sunlight shining on the lamp unit makes it difficult to tell if the lamp unit is illuminated. In order to solve this problem, most people generally have to cover the lamp unit with one's hand in order to block out the sunlight. This can be extremely inconvenient to a user especially if one's hands are full. A second problem with current continuity testers has to do with grounding. Most current continuity testers use a clip for coupling the continuity tester to ground. A problem arises if the clip is too small to attach to a grounded element. For example, an alligator clip can only be open a certain distance. If the thickness of the grounding element is bigger than the opening of the alligator clip, then another grounding element needs to be found in order to ground the continuity tester.

Therefore, a need existed to provide an improved continuity tester. The improved continuity tester must over come the problems associated with prior art continuity testers. The improved continuity tester must have a way of signaling a user that continuity exists in a conductor when the continuity tester is used outdoors or in areas where there is bright light. The improved continuity tester must further have a way of more effectively grounding the continuity tester.

### SUMMARY OF THE INVENTION

In accordance with one embodiment of the present invention, it is an object of the present invention to provide an improved continuity tester.

It is another object of the present invention to provide an improved continuity tester that over comes the problems associated with prior art continuity testers.

It is another object of the present invention to provide an improved continuity tester that has a way of signaling a user that continuity exists in a conductor when the continuity tester is used outdoors or in areas where there is bright light.

It is another object of the present invention to provide an improved continuity tester that has a way of more effectively grounding the continuity tester.

### BRIEF DESCRIPTION OF THE EMBODIMENTS

In accordance with one embodiment of the present invention a continuity testing device is disclosed. The continuity testing device has a probe element for contacting a conductor. A continuity testing circuit is coupled to the probe element. The continuity testing circuit has at least one of a vibrating or audible sensor to indicate electrical continuity of the conductor. A grounding wire is coupled to the continuity testing circuit. The grounding wire has a magnetic contact coupled thereto to ground the continuity testing device to any ferrous metallic grounded element. A housing is provided for holding and storing the probe element and the continuity testing circuit.

In accordance with one embodiment of the present invention a continuity testing device is disclosed. The continuity testing device has a probe element for contacting a conductor. A continuity testing circuit is coupled to the probe element. The continuity testing circuit has at least one of a vibrating or audible sensor to indicate electrical continuity of the conductor and a visual signal to indicate electrical continuity of the conductor. A grounding wire is coupled to the continuity testing circuit. The grounding wire has a magnetic contact coupled thereto to ground the continuity testing device to any metallic grounded element. A clamp connector is also coupled to the grounding wire to ground the continuity testing device to any grounded element. A housing is provided for holding and storing the probe element and the continuity testing circuit.

The foregoing and other objects, features, and advantages of the invention will be apparent from the following, more particular, description of the preferred embodiments of the invention, as illustrated in the accompanying drawing.

### BRIEF DESCRIPTION OF THE DRAWINGS

The invention itself, as well as a preferred mode of use, and advantages thereof, will best be understood by reference to the following detailed description of illustrated embodiment when read in conjunction with the accompanying drawings, wherein like reference numerals and symbols represent like elements.

FIG. 1 is an elevated perspective view of the continuity tester of the present invention.

FIG. 2 is an exploded view of the continuity tester of the present invention.

FIG. 3 is an exploded view of the continuity tester of the present invention with a spring connector coupled to the probe.

FIG. 4 is a cross-sectional view of the continuity tester of the present invention.

FIG. 5 is top view of the grounding magnet used in the continuity tester of the present invention showing the internal wire connections.

FIG. 6 is a cross-sectional view of the grounding magnet depicted in FIG. 5.

### DETAILED DESCRIPTION OF THE PREFERRED EMBODIMENT

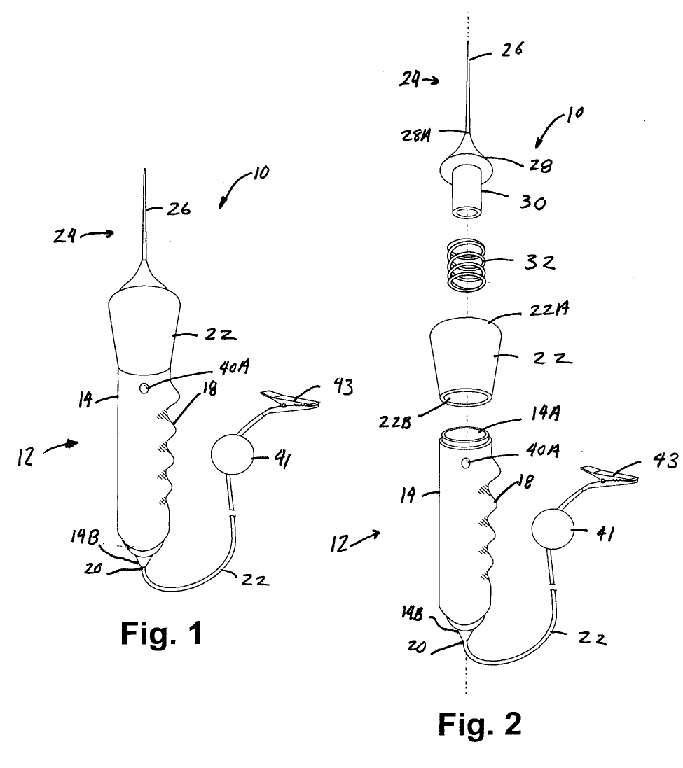

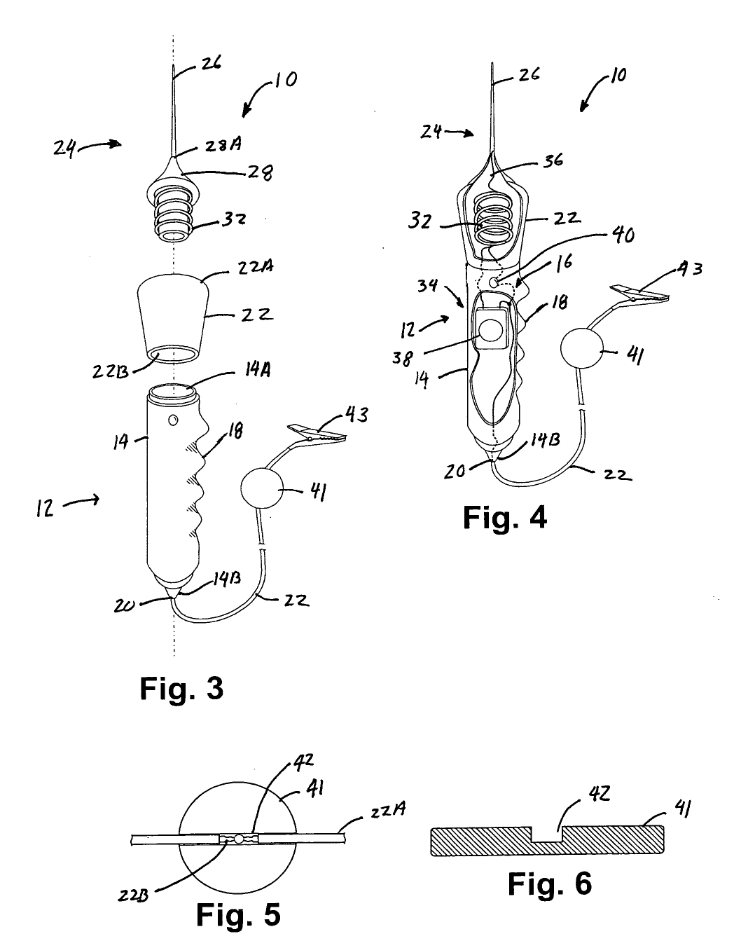

Referring to the FIGS. 1-4 a continuity tester 10 is shown. The continuity tester 10 is used to determine whether or not circuit continuity exists in an electrical conductor. The continuity tester 10 has a main body section 12. The main body section 12 is comprised of a hollow container 14. In accordance with one embodiment of the present invention, the hollow container 14 is shaped as an elongated tube. However, the hollow container 14 can come in other shapes and sizes without departing from the spirit and scope of the present invention.

The hollow container 14 is generally made of a lightweight and sturdy material that is non-conductive. A material such as a plastic, fiberglass, or the like is used. The listing of the above are given as examples and should not be seen as to limit the scope of the present invention.

The hollow container 14 has an open top surface 14A. The open top surface 14A allows one to insert and store the internal circuitry 16 of the continuity tester 10 inside the hollow container 14. One or more indentations 18 may be formed on the exterior of the hollow container 14. The indentations 18 will form a hand grip so that a user may form a tighter grip around the continuity tester 10. The hollow container 14 will have a small opening 20 located at a bottom end 14B of the hollow container 14. The opening 20 is used to allow a grounding wire 22 to extend out of the hollow container 14.

A grip 22 is coupled to the open top surface 14A of the hollow container 14. The grip 22 is used to secure a probe 24 to the hollow container 14. The grip 22 is further used to help a person get a firmer hold on the continuity tester 10. The grip 22 is generally formed of a nonconductive material, slip resistant material. In general, rubber or a like material is used.

The grip 22 will have an opening 22A located at a top surface thereof. The opening 22A is used to secure the probe 24 to the grip 22. A second opening 22B is located at a bottom surface of the grip 22. The second opening 22B is used to secure the grip 22 to the hollow container 14. The second opening 22B will generally fit over the open top surface 14A of the hollow container 14. In accordance with another embodiment of the present invention, the seconding opening 22B will have ridges formed along an interior surface thereof. The ridges will mate with ridges formed on an exterior surface of the open top surface 14A thus allowing the grip 22 to be rotatably coupled to the hollow container 14.

The probe 24 is comprised of a needle 26. The needle 26 is used to contact an electric conductor when checking for electrical continuity. The needle 26 is generally made out of a conductive metallic material. A housing 28 is coupled to a lower end section of the needle 26. The housing 28 is generally conical in shape. However, other shapes may be used without departing from the spirit and scope of the present invention. The housing 28 will have a small opening 28A located at a top section thereof. The opening 28A is where the needle 26 is inserted into the housing 28. A tubular member 30 extends out of a bottom section 28B of the housing 28. The tubular member 30 is used for two purposes. First, the tubular member 30 is used to couple the housing 28 to the grip 22. The tubular member 30 is inserted into the opening 22A of the grip 22. The tubular member 30 is further used to hold a spring contact 32. The spring contact 32 being slid over the tubular member 30. The tubular member 30 is generally made out of the same material as the housing 28.

A continuity testing circuit 34 is stored inside the hollow container 14. The continuity testing circuit 34 is coupled to the needle 26 via the spring contact 32. As seen more clearly in FIG. 4, a conductor 36 has a first end coupled to the needle 26 and a second end coupled to the spring contact 32. The continuity testing circuit 34 is also coupled to the spring contact 32. The continuity testing circuit 34 has a vibration and/or buzzing unit 38. The vibration and/or buzzing unit 38 will vibrate and/or make an audible signal when continuity exists in a conductor when testing. A light signaling device 40 is coupled in parallel to the vibration and/or buzzing unit 38. The light signaling device 40 will give a visual signal when continuity exists in the conductor when testing. A small opening 40A is formed in the hollow container 14 so that the light signaling device 40 may extend through and be seen by a user. In general, the vibration and/or buzzing unit 38 and the light signaling device 40 are low voltage devices that operate in the 6-12 volt range. The low voltage from the electrical conductor under test is used to power these devices. In order to prevent an over load on the vibration and/or buzzing unit 38 and the light signaling device 40, a resistive element may be coupled to the vibration and/or buzzing unit 38 and the light signaling device 40. By having two different signaling devices, a user will be more aware if continuity exists in a conductor. The vibration and/or buzzing unit 38 are especially beneficial when testing a conductor outside and the sunlight is too bright and hinders visibility of the light signaling device 40.

A grounding wire 22 extends off of the continuity testing circuit 34. A magnetic contact 41 is coupled to the grounding wire 22. As may be seen more clearly in FIG. 5 and 6, a channeling 42 is formed in the magnetic contact 41. The insulation 22A of the ground wire 22 is partially striped to reveal a conductor 22B. The conductor 22B is coupled to the magnetic contact 41. This will allow the magnetic contact 41 to be placed on a grounded ferrous metallic object to ground the continuity tester 10. A clamp connector 43 is also coupled to the ground wire 22. The clamp connector 43 is also used to ground the continuity tester 10. By having two separate grounding units, it is much easier to ground the continuity tester 10. The magnetic contact 41 will allow one to ground the continuity tester to any ferrous metallic grounded object.

While the invention has been particularly shown and described with reference to preferred embodiments thereof, it will be understood by those skilled in the art that the foregoing and other changes in form and details may be made therein without departing from the spirit and scope of the invention.

1. A continuity testing device comprising:
a probe element for contacting a conductor;
a continuity testing circuit coupled to the probe element, wherein the continuity testing circuit has at least one of a vibrating or audible sensor to indicate electrical continuity of the conductor;
a grounding wire coupled to the continuity testing circuit wherein the grounding wire has a magnetic contact coupled thereto to ground the continuity testing device to any ferrous metallic grounded element; and
a housing for holding and storing the probe element and the continuity testing circuit.

2. A continuity testing device in accordance with claim 1 wherein the continuity testing circuit further comprises a visual signal to indicate electrical continuity of the conductor.

3. A continuity testing device in accordance with claim 1 wherein the grounding wire further has a clamp connector coupled thereto to ground the continuity testing device to any grounded element.

4. A continuity testing device in accordance with claim 1 further comprising a spring contact for coupling the probe element to the continuity testing circuit.

5. A continuity testing device in accordance with claim 1 wherein the housing comprises:
a hollow handle for storing the continuity testing circuit;
a probe housing for securing the probe element; and
a grip member for coupling the probe housing to the hollow handle.

6. A continuity testing device in accordance with claim 5 wherein the hollow handle has a top opening for inserting the continuity testing circuit into the hollow handle and a bottom opening for allowing the grounding wire to extend out of the hollow handle.

7. A continuity testing device in accordance with claim 5 wherein the hollow handle has a plurality of ridges formed along a side of the hollow handle, the ridges forming a hand grip.

8. A continuity testing device in accordance with claim 5 wherein the probe housing comprises:
a conical body having a small opening formed at a top surface thereof for holding the probe element; and
a tubular member extending down from a bottom section of the conical body, the tubular member being used to couple the probe housing to the grip member.

9. A continuity testing device in accordance with claim 5 wherein the grip member has a first opening at a top surface thereof for coupling the probe housing to the grip member and a second opening at a bottom surface thereof for coupling the grip member to the hollow handle.

10. A continuity testing device comprising:
a probe element for contacting a conductor;
a continuity testing circuit coupled to the probe element, wherein the continuity testing circuit has at least one of a vibrating or audible sensor to indicate electrical continuity of the conductor and a visual signal to indicate electrical continuity of the conductor;
a grounding wire coupled to the continuity testing circuit wherein the grounding wire has a magnetic contact coupled thereto to ground the continuity testing device to any ferrous metallic grounded element and a clamp connector coupled thereto to ground the continuity testing device to any grounded element; and
a housing for holding and storing the probe element and the continuity testing circuit.

11. A continuity testing device in accordance with claim 10 further comprising a spring contact for coupling the probe element to the continuity testing circuit.

12. A continuity testing device in accordance with claim 10 wherein the housing comprises:
a hollow handle for storing the continuity testing circuit;
a probe housing for securing the probe element; and
a grip member for coupling the probe housing to the hollow handle.

13. A continuity testing device in accordance with claim 12 wherein the hollow handle has a top opening for inserting the continuity testing circuit into the hollow handle and a bottom opening for allowing the grounding wire to extend out of the hollow handle.

14. A continuity testing device in accordance with claim 13 wherein the hollow handle has a plurality of ridges formed along a side of the hollow handle, the ridges forming a hand grip.

15. A continuity testing device in accordance with claim 12 wherein the probe housing comprises:
a conical body having a small opening formed at a top surface thereof for holding the probe element; and
a tubular member extending down from a bottom section of the conical body, the tubular member being used to couple the probe housing to the grip member.

16. A continuity testing device in accordance with claim 12 wherein the grip member has a first opening at a top surface thereof for coupling the probe housing to the grip member and a second opening at a bottom surface thereof for coupling the grip member to the hollow handle.
